(19) United States
(12) Patent Application Publication
(10) Pub. No.: US 2026/0101823 A1
(43) Pub. Date: Apr. 9, 2026

(54) SEMICONDUCTOR PACKAGE

(71) Applicant: SAMSUNG ELECTRONICS CO., LTD., SUWON-SI (KR)

(72) Inventors: Seokbeom YONG, Suwon-si (KR); Eunkyeong PARK, Suwon-si (KR); Sungoh AHN, Suwon-si (KR)

(73) Assignee: SAMSUNG ELECTRONICS CO., LTD., SUWON-SI (KR)

(21) Appl. No.: 19/272,595

(22) Filed: Jul. 17, 2025

(30) Foreign Application Priority Data
Oct. 8, 2024 (KR) 10-2024-0136825

(51) Int. Cl. H01L 25/065; H01L 23/482; H01L 23/49

(52) U.S. Cl. CPC H10W 90/00; H10W 20/40; H10W 72/50; H10W 72/823

(57) ABSTRACT

A semiconductor package includes a package substrate, a bridge chip structure including a plurality of bridge chips that are accommodated in the package substrate and stacked in a vertical direction, and a plurality of semiconductor chips that are arranged on the package substrate and are electrically connected to each other through the bridge chip structure, wherein each of the plurality of bridge chips has different sizes.

### CROSS-REFERENCE TO RELATED APPLICATION

This application is based on and claims priority under 35 U.S. C. § 119 to Korean Patent Application No. 10-2024-0136825, filed on Oct. 8, 2024, in the Korean Intellectual Property Office, the disclosure of which is incorporated by reference herein in its entirety.

### BACKGROUND

The inventive concept relates to a semiconductor package. More specifically, the inventive concept relates to a semiconductor package including a silicon bridge.

Recently, the demand for portable devices has been rapidly increasing in the electronic product market, and as a result, there is ongoing demand for the miniaturization and weight reduction of electronic components installed in electronic products. In order to miniaturize and reduce the weight of electronic components, semiconductor packages mounted on the electronic components are required to be smaller in size while processing large amounts of data.

### SUMMARY

The inventive concept provides a semiconductor package having improved integration by including a plurality of silicon bridges having different sizes from each other and by stacking and arranging the plurality of silicon bridges.

In addition, the problems to be solved by the technical spirit of the present inventive concept are not limited to the problems mentioned above, and other problems not mentioned will be clearly understood by those skilled in the art from the following description.

According to an aspect of the inventive concept, there is provided a semiconductor package including a package substrate, a bridge chip structure including a plurality of bridge chips that are accommodated in the package substrate and are stacked in a vertical direction, and a plurality of semiconductor chips that are arranged on the package substrate and are electrically connected to each other through the bridge chip structure, wherein each of the plurality of bridge chips has different sizes.

According to another aspect of the inventive concept, there is provided a semiconductor package including a package substrate, a bridge chip structure including a plurality of bridge chips accommodated in the package substrate and stacked in a vertical direction, and a plurality of semiconductor chips arranged on the package substrate and electrically connected to each other through the bridge chip structure, wherein the plurality of bridge chips include a first bridge chip having a first width in a first horizontal direction, and a second bridge chip attached to a lower surface of the first bridge chip and having a second width greater than the first width in the first horizontal direction, and the second bridge chip further includes a first through-via passing through the second bridge chip in the vertical direction.

According to another aspect of the inventive concept, there is provided a semiconductor package including a wiring structure and a cavity, a bridge chip structure including a first bridge chip and a second bridge chip, wherein the first bridge chip is accommodated in the package substrate and has a first width in a first horizontal direction; and the second bridge chip is vertically stacked on a lower surface of the first bridge chip and has a second width greater than the first width in the first horizontal direction, and a plurality of semiconductor chips, each of which includes a first region and a second region, wherein the first region is electrically connected to the first bridge chip, the second region is electrically connected to the second bridge chip, and the first region and the second region are arranged on the package substrate in the first horizontal direction,

### BRIEF DESCRIPTION OF THE DRAWINGS

Embodiments will be more clearly understood from the following detailed description taken in conjunction with the accompanying drawings in which:

FIG. 1 is a schematic cross-sectional view showing a configuration of a semiconductor package according to an embodiment;

FIG. 2 is an enlarged cross-sectional view of a portion “EX1” of FIG. 1;

FIG. 3 is a schematic plan view showing a configuration of a bridge chip structure of a semiconductor package according to an embodiment;

FIG. 4A, FIG. 4B and FIG. 4C are schematic plan views showing a configuration of a bridge chip structure of a semiconductor package according to an embodiment;

FIG. 5A is a schematic cross-sectional view showing a configuration of a semiconductor package according to an embodiment;

FIG. 5B is a schematic enlarged cross-sectional view showing a portion “EX2” of FIG. 5A;

FIG. 6A is a schematic cross-sectional view showing a configuration of a semiconductor package according to an embodiment;

FIG. 6B is a schematic enlarged cross-sectional view showing a portion “EX3” of FIG. 6A; and

FIG. 7, FIG. 8, FIG. 9, FIG. 10, FIG. 11 and FIG. 12 are cross-sectional views sequentially showing a method of manufacturing a semiconductor package according to an embodiment.

### DETAILED DESCRIPTION OF THE EMBODIMENTS

Hereinafter, embodiments of the inventive concept will be described in detail with reference to the accompanied drawings. In the drawings, like reference numbers may be assigned to like components in different embodiments, and the descriptions thereof will not be repeated.

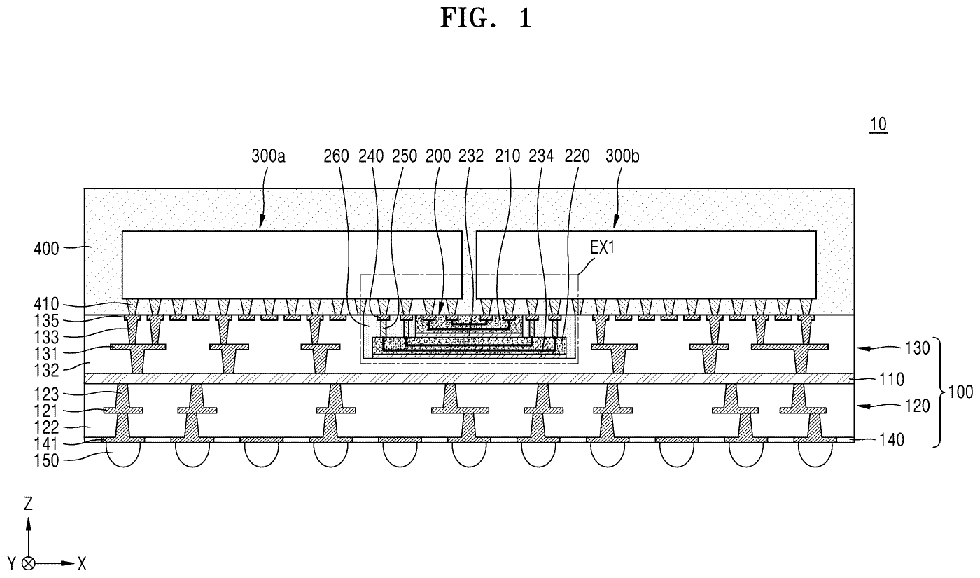

FIG. 1 is a schematic cross-sectional view showing a configuration of a semiconductor package 10 according to an embodiment.

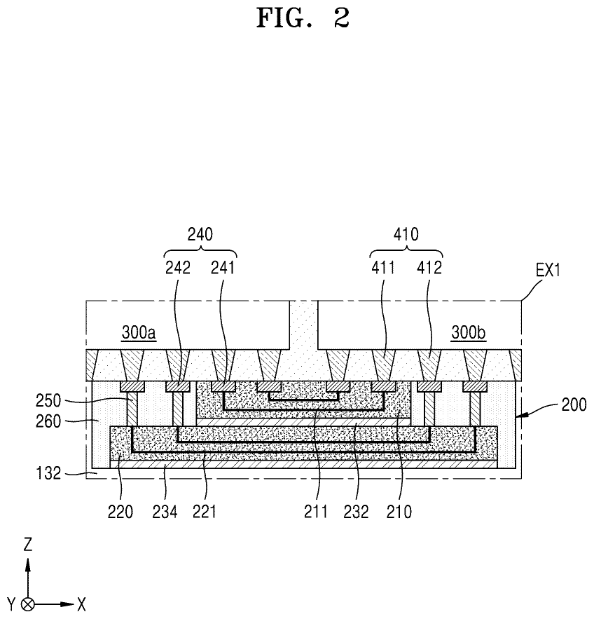

FIG. 2 is an enlarged cross-sectional view of a portion “EX1” of FIG. 1.

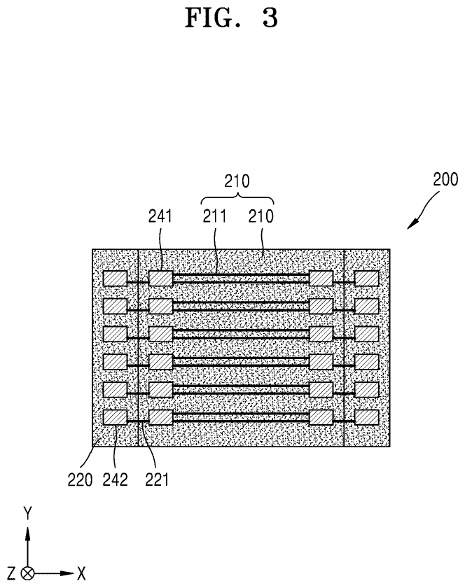

FIG. 3 is a schematic plan view showing a configuration of a bridge chip structure of the semiconductor package according to an embodiment.

Referring to FIGS. 1 to 3, the semiconductor package 10 according to an embodiment may include a package substrate 100, a bridge chip structure 200, a plurality of semiconductor chips 300a and 300b, and a sealant 400.

According to embodiments, the package substrate 100 may include, for example, a ceramic substrate, a Printed Circuit Board (PCB), an organic substrate, an interposer substrate, etc. In some embodiments, the package substrate 100 may include an active wafer, such as a silicon wafer.

The package substrate 100 may include a core layer 110, a lower wiring structure 120, an upper wiring structure 130, and a protective layer 140. The core layer 110 may include glass fiber, such as FR4 and a resin. In addition, the core layer may include a bismaeleimide-triazine (BT) resin, a poly carbonate (PC) resin, a buildup film such as ajinomoto build-up film (ABF), or other laminate resins. In some embodiments, the core layer may be omitted.

In example embodiments, the lower wiring structure 120 may be arranged under the core layer 110. The lower wiring structure 120 may include a plurality of lower conductive layers 121, a plurality of lower conductive vias 123, and a lower insulating layer 122. The lower insulating layer 122 is disposed below the core layer 110 and may include a plurality of stacked layers. The lower insulating layer 122 may cover a plurality of lower conductive layers 121 and a plurality of lower conductive vias 123.

In example embodiments, the plurality of lower conductive layers 121 and the plurality of lower conductive vias 123 may be provided within the lower insulating layer 122. The plurality of lower conductive layers 121 may be spaced apart from each other in the vertical direction Z within the lower insulating layer 122 and may extend in a horizontal direction X and/or Y, respectively. For example, the plurality of lower conductive layers 121 may be disposed at different vertical levels of the semiconductor package 10 to form a multilayer wiring structure. The plurality of lower conductive vias 123 may extend between the plurality of lower conductive layers 121 positioned at different vertical levels, respectively, to electrically connect the plurality of lower conductive layers 121 positioned at different vertical levels in the vertical direction Z.

In the present specification, the first horizontal direction X and the second horizontal direction Y may be directions intersecting each other among horizontal directions. For example, the first horizontal direction X and the second horizontal direction Y may be directions intersecting each other perpendicularly. The vertical direction Z may be a direction intersecting both the first horizontal direction X and the second horizontal direction Y. For example, the vertical direction Z may be a direction perpendicular to the first horizontal direction X and the second horizontal direction Y.

In addition, the plurality of lower conductive vias 123 may electrically connect the plurality of lower conductive layers 121 to the plurality of lower pads 141. In addition, the plurality of lower conductive vias 123 may electrically connect the plurality of lower conductive layers 121 to the core layer 110.

In example embodiments, the upper wiring structure 130 may be disposed on top of the core layer 110. The upper wiring structure 130 may include a plurality of upper conductive layers 131, a plurality of upper conductive vias 133, a plurality of upper pads 135, and an upper insulating layer 132. The upper insulating layer 132 is disposed on top of the core layer 110 and may include a plurality of stacked layers. The upper insulating layer 132 may cover the plurality of upper conductive layers 131, the plurality of upper conductive vias 133, and the plurality of upper pads 135.

In example embodiments, the plurality of upper conductive layers 131, the plurality of upper conductive vias 133, and the plurality of upper pads 135 may be provided within the upper insulating layer 132 in the vertical direction Z. The plurality of upper conductive layers 131 are spaced apart from each other in the vertical direction Z within the upper insulating layer 132 and may each extend in the horizontal direction X and/or Y. For example, a plurality of upper conductive layers 131 may be arranged at different vertical levels to form a multi-layer wiring structure in the vertical direction Z. A plurality of upper conductive vias 133 may extend between a plurality of upper conductive layers 131 arranged at different vertical levels in the vertical direction Z, respectively, to electrically connect the plurality of upper conductive layers 131 located at different vertical levels.

In addition, the plurality of upper conductive vias 133 may electrically connect the plurality of upper conductive layers 131 to the plurality of upper pads 135. In addition, the plurality of upper conductive vias 133 may electrically connect the plurality of upper conductive layers 131 to the core layer 110. In example embodiments, the number of layers of the lower wiring structure 120 and the upper wiring structure 130 may be the same or different from each other.

In example embodiments, upper surfaces and side walls of the plurality of upper pads 135 may be covered by the upper insulating layer 132. The upper surfaces of the plurality of upper pads 135 may form coplanar with an upper surface of the upper insulating layer 132. The plurality of upper pads 135 may include copper (Cu).

In example embodiments, the lower insulating layer 122 and the upper insulating layer 132 may each include, but are not limited to, a prepreg. For example, the lower insulating layer 122 and the upper insulating layer 132 may each include at least one material selected from a phenol resin, an epoxy resin, and a polyimide. The lower insulating layer 122 and the upper insulating layer 132 may each include at least one material selected from among frame retardant 4 (FR-4), tetrafunctional epoxy, polyphenylene ether, epoxy/polyphenylene oxide, BT, thermount, cyanate ester, polyimide, and liquid crystal polymer.

The conductive patterns, such as the plurality of lower conductive layers 121, the plurality of lower conductive vias 123, the plurality of upper conductive layers 131, and the plurality of upper conductive vias 133, may include, for example, a metal or an alloy of metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like, but are not limited thereto. In some embodiments, the conductive patterns may be formed by stacking a metal or an alloy of metals on a seed layer including Cu, Ti, titanium nitride (TiN), or titanium tungsten (TiW).

In some embodiments, the package substrate 100 may be a redistribution substrate. In such a case, the package substrate 100 may not include a separate core layer, but may include an interlayer insulating layer of a photo-imageable dielectric (PID) resin and wirings of multilayer.

In example embodiments, the protective layer 140 may be arranged on a lower surface of the lower wiring structure 120. The lower surface of the protective layer 140 may have the same surface as lower surfaces of the plurality of lower pads 141. However, the lower surface of the protective layer 140 does not necessarily have the same surface as the lower surfaces of the lower pads 141, and the lower surface of the protective layer 140 may be positioned higher than the lower surfaces of the lower pads 141 in the vertical direction Z. The protective layer 140 may include, for example, a solder resist, but the material of the protective layer 140 is not limited to the solder resist. The plurality of lower pads 141 may be electrically separated by the protective layer 140.

In example embodiments, an external connection terminal 150, such as a solder ball, may be arranged on the lower surfaces of the plurality of lower pads 141. The external connection terminal 150 may connect the semiconductor package 10 to a package substrate of an external system, or a main board of an electronic device such as a mobile device. The external connection terminal 150 may include at least one of a conductive material, for example, solder, tin (Sn), silver (Ag), copper (Cu), and aluminum (Al). However, the material of the external connection terminal 150 is not limited to the materials described above.

In example embodiments, the bridge chip structure 200 may be accommodated in the package substrate 100. For example, the bridge chip structure 200 may be placed in a cavity C (see FIG. 10) of the package substrate 100. At this time, an upper surface of the bridge chip structure 200 may be coplanar with an upper surface of the upper wiring structure 130.

In example embodiments, the bridge chip structure 200 may be formed within the package substrate 100 and configured to electrically connect the package substrate 100 to a plurality of semiconductor chips 300a and 300b. The bridge chip structure 200 may include a plurality of bridge chips stacked in the vertical direction Z. For example, the bridge chip structure 200 may include a first bridge chip 210 and a second bridge chip 220 in the vertical direction Z. The first bridge chip 210 may be stacked on the second bridge chip 220 in the vertical direction Z. Although the bridge chip structure 200 is illustrated as including the first and second bridge chips 210 and 220 in FIGS. 1 and 2, the present embodiment is not limited thereto, and the bridge chip structure 200 may include three or more bridge chips.

In example embodiments, an upper surface of the first bridge chip 210 may be a surface adjacent to an active surface of the semiconductor substrate constituting the first bridge chip 210, and a lower surface of the first bridge chip 210 may be a surface adjacent to an inactive surface of the semiconductor substrate constituting the first bridge chip 210. In addition, an upper surface of the second bridge chip 220 may be a surface adjacent to an active surface of the semiconductor substrate constituting the second bridge chip 220, and a lower surface of the second bridge chip 220 may be a surface adjacent to an inactive surface of the semiconductor substrate constituting the second bridge chip 220.

In example embodiments, the plurality of bridge chips stacked in the vertical direction Z may have different sizes. At this time, the plurality of bridge chips may become larger in size as they get farther away from an upper surface of the package substrate 100. For example, the plurality of bridge chips may be arranged in a step shape that increases in size as they get farther away from the upper surface of the package substrate 100.

Specifically, among the plurality of bridge chips, the bridge chip attached downward in the vertical direction Z may have a greater width in the same direction as the direction in which the plurality of semiconductor chips 300a and 300b are arranged. For example, in the case when the plurality of semiconductor chips 300a and 300b are arranged in the first horizontal direction X as in the semiconductor package 10 illustrated in FIGS. 1 and 2, the bridge chip attached downward in the vertical direction Z among the plurality of bridge chips may have a greater width in the first horizontal direction. For example, the first bridge chip 210 may have a first width in the first horizontal direction X, and the second bridge chip 220 may have a second width in the first horizontal direction X. At this time, the second width may be greater than the first width. At this time, widths of the first bridge chip 210 and the second bridge chip 220 in the second horizontal direction Y may be the same but are not limited thereto.

In example embodiments, the first bridge chip 210 may include a plurality of first bridge circuits 211 therein. The first bridge circuit 211 may be configured to electrically connect first regions of the plurality of semiconductor chips 300a and 300b. For example, the first region of the first semiconductor chip 300a may be electrically connected to the first region of the second semiconductor chip 300b via the first bridge circuit 211. The second bridge chip 220 may include a plurality of second bridge circuits 221 therein. The second bridge circuit 221 may be configured to electrically connect the second regions of the plurality of semiconductor chips 300a and 300b. For example, the second region of the first semiconductor chip 300a may be electrically connected to the second region of the second semiconductor chip 300b via the second bridge circuit 221.

In example embodiments, the plurality of first bridge circuits 211 may be arranged to be spaced apart in the second horizontal direction Y and/or the vertical direction Z within the first bridge chip 210, and may extend in the first horizontal direction X. The plurality of second bridge circuits 221 may be arranged to be spaced apart in the second horizontal direction Y and/or the vertical direction Z within the second bridge chip 220, and may extend in the first horizontal direction X. At this time, the vertical level of the plurality of second bridge circuits 221 may be lower than the vertical level of the plurality of first bridge circuits 211. By stacking and arranging the plurality of bridge chips 210 and 220, the plurality of bridge circuits 211 and 221 may be arranged to overlap in the vertical direction Z.

In example embodiments, the bridge chip structure 200 may include a plurality of upper bridge pads 240. The plurality of upper bridge pads 240 may be coplanar with the upper surface of the bridge chip structure 200. A first upper bridge pad 241 may be electrically connected to the first bridge circuit 211 of the first bridge chip 210. The first upper bridge pad 241 may be electrically connected to the first region of the plurality of semiconductor chips 300a and 300b through a plurality of first connection terminals 411. A second upper bridge pad 242 may be electrically connected to the second bridge circuit 221 of the second bridge chip 220. The second upper bridge pad 242 may be electrically connected to the second region of the plurality of semiconductor chips 300a and 300b through a plurality of second connection terminals 412.

In example embodiments, the bridge chip structure 200 may further include a plurality of vertical wires 250 connecting the second bridge circuit 221 to the second upper bridge pad 242. The plurality of vertical wires 250 may extend in the vertical direction Z between the second bridge chip 220 and the second upper bridge pad 242. The plurality of vertical wires 250 may electrically connect the second bridge chip 220 to the second region of the plurality of semiconductor chips 300a and 300b. Also, although not shown, if the bridge chip structure 200 includes three or more bridge chips, the remaining bridge chips except for the bridge chip positioned at the top may be electrically connected to the plurality of vertical wires 250. At this time, the plurality of vertical wires 250 may include, but are not limited to, gold (Au), aluminum (Al), and copper (Cu).

In example embodiments, the plurality of vertical wires 250 may be arranged to be spaced apart from the first bridge chip 210 in the horizontal direction X. For example, if the plurality of semiconductor chips 300a and 300b are arranged in the first horizontal direction X, the plurality of vertical wires 250 may be arranged to be spaced apart from the first bridge chip 210 in the first horizontal direction X but are not limited thereto. In addition, the plurality of vertical wires 250 may be arranged to be spaced apart from each other in the horizontal direction X with the first bridge chip 210 therebetween. At this time, a length of the plurality of vertical wires 250 in the vertical direction Z may be greater than a height of the first bridge chip 210 in the vertical direction Z.

In the case of a bridge chip structure of the semiconductor package according to the comparative example, a wider area is required in the horizontal direction (for example, the second horizontal direction Y) to arrange multiple bridge circuits, and accordingly, there are problems in that the manufacturing difficulty of the semiconductor package increases and the structural stability deteriorates.

On the other hand, the semiconductor package 10 according to an embodiment includes a bridge chip structure 200 in which multiple bridge chips 210 and 220 are stacked in the vertical direction Z, thereby reducing the area of the bridge chip structure 200 and improving the integration degree. By stacking and arranging multiple bridge chips 210 and 220, multiple bridge circuits 211 and 221 may be arranged to overlap in the vertical direction Z. Therefore, the number of multiple bridge circuits 211 and 221 may be increased while minimizing the area of the bridge chip structure 200.

In addition, by arranging the second bridge chip 220 greater than the first bridge chip 210 at the bottom of the first bridge chip 210, the second bridge chip 220 may be electrically connected to the multiple semiconductor chips 300a and 300b through the plurality of vertical wires 250. By electrically connecting the second bridge chip 220 to the plurality of semiconductor chips 300a and 300b through the plurality of vertical wires 250, a structure such as a through silicon via (TSV) passing through the first bridge chip 210 at the top may be omitted, thereby reducing the manufacturing difficulty of the semiconductor package 10.

In example embodiments, a first adhesive layer 232 may be disposed between the first bridge chip 210 and the second bridge chip 220. The first adhesive layer 232 may be configured to bond the lower surface of the first bridge chip 210 and the upper surface of the second bridge chip 220. The first adhesive layer 232 may include a material that electrically insulates the first bridge chip 210 and the second bridge chip 220. In addition, a second adhesive layer 234 may be disposed between the second bridge chip 220 and the upper wiring structure 130 of the package substrate 100. The second adhesive layer 234 may be configured to bond the lower surface of the second bridge chip 220 to the upper surface of the upper wiring structure 130. The second adhesive layer 234 may include a material that electrically insulates the second bridge chip 220 from the upper wiring structure 130.

In example embodiments, the bridge chip structure 200 may include an encapsulation layer 260 covering the first bridge chip 210, the second bridge chip 220, and the plurality of vertical wires 250. The encapsulation layer 260 may be disposed on the package substrate 100 to encapsulate the bridge chip structure 200. Specifically, the encapsulation layer 260 may be formed to fill an interior of a cavity C (see FIG. 10) and cover the bridge chip structure 200 and the upper wiring structure 130. The encapsulating layer 260 may include, but is not limited to, a thermosetting resin such as an epoxy resin, a thermoplastic resin such as a polyimide, or a resin including a reinforcing material such as an inorganic filler, specifically, an ABF, FR-4, BT, etc., and the encapsulation layer 260 may include a molding material such as an epoxy mold compound (EMC) or a photosensitive material such as photo-imagable encapsulant (PIE).

In example embodiments, the semiconductor package 10 may include a plurality of semiconductor chips 300a and 300b arranged in the horizontal direction X on the package substrate 100. In FIG. 1, the plurality of semiconductor chips 300a and 300b are illustrated as being arranged to be spaced apart in the first horizontal direction X but are not limited thereto. For example, the plurality of semiconductor chips 300a and 300b may be arranged spaced apart in the first horizontal direction X and/or the second horizontal direction Y.

In example embodiments, the first semiconductor chip 300a may be configured to be electrically connected to the second semiconductor chip 300b. The plurality of semiconductor chips 300a and 300b may each include the first region electrically connected to the first bridge chip 210 and the second region electrically connected to the second bridge chip 220. The first region and the second region may each include a circuit pattern. The first region may be a core power region of a logic semiconductor chip. The second region may be a physical layer of a logic semiconductor chip. The physical layer may perform a role of converting and transmitting data of a terminal into an electrical signal in the logic semiconductor chip and receiving the electrical signal and interpreting the electrical signal as data.

In example embodiments, the first region of each of the plurality of semiconductor chips 300a and 300b may overlap with the bridge chip structure 200 in the vertical direction Z. In addition, the second region of each of the plurality of semiconductor chips 300a and 300b may overlap with the bridge chip structure 200 in the vertical direction Z.

In example embodiments, the plurality of semiconductor chips 300a and 300b may include a logic chip, a memory chip, or a bridge chip. The memory chip may include, for example, a volatile memory chip such as a Dynamic Random Access Memory (DRAM) or an Static Random Access Memory (SRAM), or a nonvolatile memory chip such as a Phase-change Random Access Memory (PRAM), a Magnetoresistive Random Access Memory (MRAM), a Ferroelectric Random Access Memory (FeRAM), or a Resistive Random Access Memory (RRAM). The logic chip may include, for example, a microprocessor such as a central processing unit (CPU), a graphic processing unit (GPU), or an application processor (AP), an analog device, or a digital signal processor. Alternatively, the plurality of semiconductor chips 300a and 300b may be High Bandwidth Memory (HBM) chips that stack DRAMs in multiple layers to increase bandwidth.

In example embodiments, a plurality of connection terminals 410 may electrically connect the plurality of semiconductor chips 300a and 300b to the bridge chip structure 200 and/or the upper wiring structure 130. Specifically, the plurality of connection terminals 410 may be electrically connected to the bridge chip structure 200 through the plurality of upper bridge pads 240, and the plurality of connection terminals 410 may be electrically connected to the upper wiring structure 130 through the plurality of upper pads 135. At this time, the plurality of first connection terminals 411 may electrically connect the first bridge chip 210 and the first region of the plurality of semiconductor chips 300a and 300b. The plurality of second connection terminals 412 may electrically connect the second bridge chip 220 and the second region of the plurality of semiconductor chips 300a and 300b.

In example embodiments, the sealant 400 may cover the plurality of semiconductor chips 300a and 300b. In addition, the sealant 400 may cover the upper surface of the upper wiring structure 130 and the connection terminal 410. The sealant 400 may include, but is not limited to, EMC.

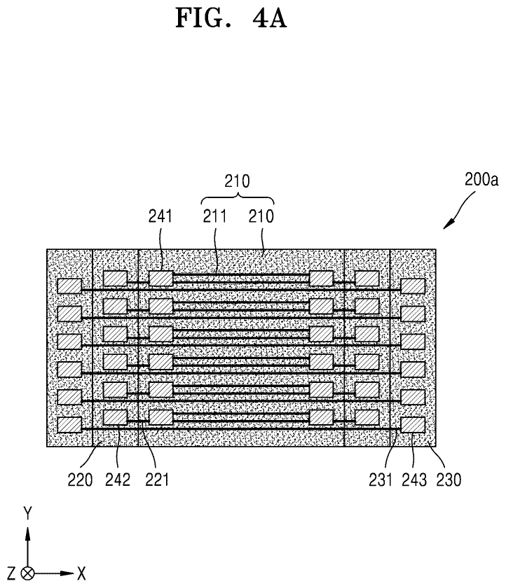

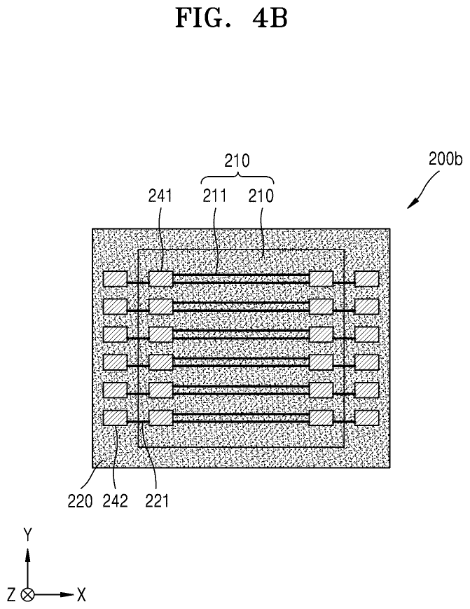

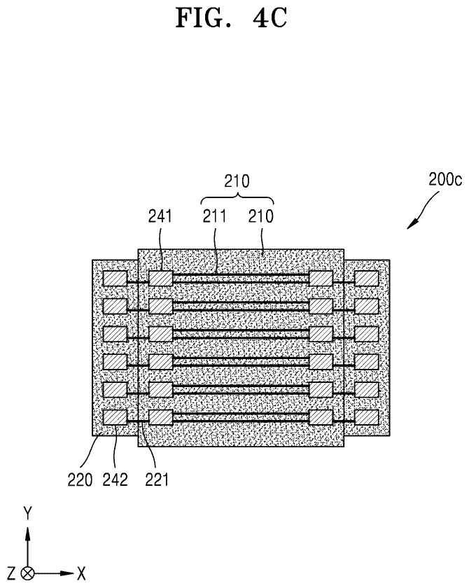

FIGS. 4A to 4C are schematic plan views showing a configuration of a bridge chip structure 200a of a semiconductor package according to an example embodiment.

In the description with reference to FIGS. 4A to 4C, like reference numerals as those in FIGS. 1 to 3 represent like members, and a detailed description thereof will not be repeated.

Referring to FIG. 4A, the bridge chip structure 200a may include a first bridge chip 210, a second bridge chip 220, and a third bridge chip 230. The second bridge chip 220 may be attached to a lower surface of the first bridge chip 210, and the third bridge chip 230 may be attached to a lower surface of the second bridge chip 220 in the vertical direction Z. At this time, the first bridge chip 210, the second bridge chip 220, and the third bridge chip 230 may have different sizes. For example, the first bridge chip 210 may have a first width in the first horizontal direction X, the second bridge chip 220 may have a second width in the first horizontal direction X, and the third bridge chip 230 may have a third width in the first horizontal direction X. At this time, the second width may be greater than the first width, and the third width may be greater than the second width. At this time, the widths of the first bridge chip 210, the second bridge chip 220, and the third bridge chip 230 in the second horizontal direction Y may be the same, but are not limited thereto.

In example embodiments, the first bridge chip 210 may include a first bridge circuit 211 therein, the second bridge chip 220 may include a second bridge circuit 221 therein, and the third bridge chip 230 may include a third bridge circuit 231 therein. The first bridge circuit 211, the second bridge circuit 221, and the third bridge circuit 231 may electrically connect the plurality of semiconductor chips 300a and 300b. The first bridge circuit 211 may be electrically connected to the plurality of semiconductor chips 300a and 300b through the first upper bridge pad 241. The second bridge circuit 221 may be electrically connected to the plurality of semiconductor chips 300a and 300b through the second upper bridge pad 242. At this time, a vertical wire 250 (see FIG. 1) extending in the vertical direction Z may be arranged between the second bridge circuit 221 and the second upper bridge pad 242. The third bridge circuit 231 may be electrically connected to the plurality of semiconductor chips 300a and 300b through the third upper bridge pad 243. At this time, the vertical wire 250 (see FIG. 1) extending in the vertical direction Z may be arranged between the third bridge circuit 231 and the third upper bridge pad 243.

Referring to FIGS. 4B and 4C, the bridge chip structure 200a may include the first bridge chip 210 and the second bridge chip 220. The second bridge chip 220 is attached to the lower surface of the first bridge chip 210 in the vertical direction Z, and the first bridge chip 210 and the second bridge chip 220 may have different sizes. For example, the first bridge chip 210 may have a first width in the first horizontal direction X, and the second bridge chip 220 may have a second width in the first horizontal direction X. At this time, the second width may be greater than the first width.

In addition, the first bridge chip 210 and the second bridge chip 220 may have different widths in the second horizontal direction Y. For example, the first bridge chip 210 may have a third width in the second horizontal direction Y, and the second bridge chip 220 may have a fourth width in the second horizontal direction Y. At this time, the third width may be greater than the fourth width (see FIG. 4B), and the third width may be less than the fourth width (see FIG. 4C).

The semiconductor package 10 of the inventive concept may include a bridge chip structure 200a, 200b, and 200c in which the plurality of bridge chips 210, 220, and 230 are stacked in the vertical direction Z, thereby reducing the area of the bridge chip structure 200a, 200b, and 200c and improving the integration degree. By stacking and arranging the multiple bridge chips 210, 220, and 230, the plurality of bridge circuits 211, 221, and 231 may be arranged to overlap in the vertical direction Z. Therefore, the number of multiple bridge circuits 211, 221, and 231 may be increased while minimizing the area of the bridge chip structure (200a, 200b, and 200c.

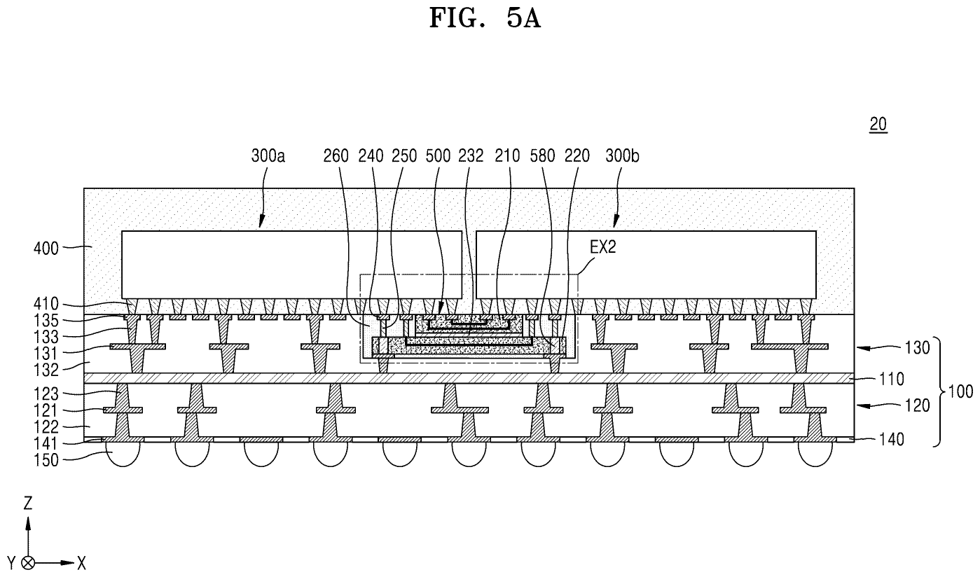

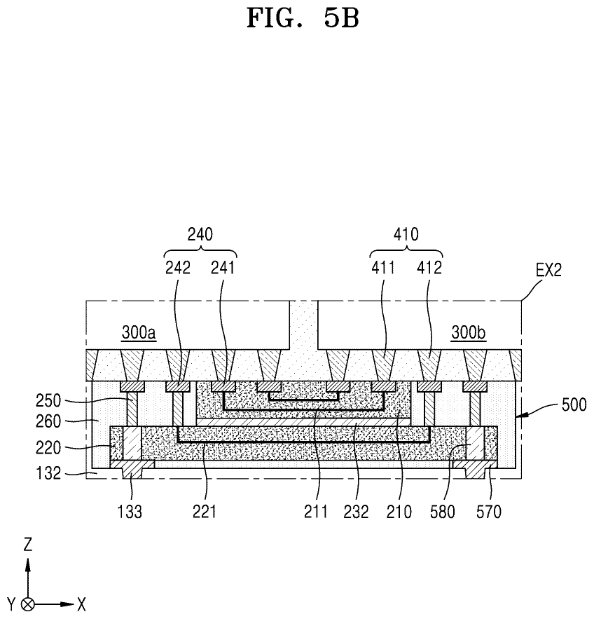

FIG. 5A is a schematic cross-sectional view showing a configuration of a semiconductor package 20 according to an embodiment.

FIG. 5B is an enlarged cross-sectional view of a portion “EX2” of FIG. 5A.

In the description with reference to FIG. 5A and FIG. 5B, like reference numerals as those in FIG. 1 to FIG. 3 represent like members, and thus, a detailed description thereof will not be repeated.

Referring to FIG. 5A and FIG. 5B, a bridge chip structure 500 of the semiconductor package 20 of the inventive concept may include a plurality of bridge chips stacked in the vertical direction Z. For example, the bridge chip structure 500 may include a first bridge chip 210 and a second bridge chip 220.

In example embodiments, the second bridge chip 220 may further include a first through-via 580. The first through-via 580 may penetrate the second bridge chip 220 in the vertical direction Z. The first through-via 580 may be arranged to penetrate the second bridge chip 220 at a position that does not overlap the first bridge chip 210 in the vertical direction Z but is not limited thereto. For example, the first through-via 580 may be positioned to penetrate the second bridge chip 220 at a position that overlaps the first bridge chip 210 in the vertical direction Z. At this time, the first through-via 580 may be a TSV but is not limited thereto.

In example embodiments, the first through via 580 may be electrically connected to a plurality of vertical wires 250. That is, the first through-via 580 may be electrically connected to the second region of the plurality of semiconductor chips 300a and 300b through the plurality of vertical wires 250.

In addition, the first through-via 580 may be electrically connected to the package substrate 100. The bridge chip structure 500 may further include a lower bridge pad 570, and the first through-via 580 may be in contact with the lower bridge pad 570. The first through-via 580 may be electrically connected to the package substrate 100 through the lower bridge pad 570 and the upper conductive via 133 of the upper wiring structure 130.

At this time, the second adhesive layer 234 (see FIG. 1) configured to bond the second bridge chip 220 and the upper wiring structure 130 of the package substrate 100 may be omitted. A plurality of lower bridge pads 570 may be arranged between the second bridge chip 220 and the upper wiring structure 130 of the package substrate 100. In addition, the encapsulation layer 260 may cover between the second bridge chip 220 and the upper wiring structure 130 of the package substrate 100 and between the plurality of lower bridge pads 570.

The semiconductor package 20 according to an embodiment includes a bridge chip structure 500 in which the plurality of bridge chips 210 and 220 are stacked in the vertical direction Z, and thus, the area of the bridge chip structure 500 is reduced and the integration degree may be improved. By stacking and arranging a plurality of bridge chips 210 and 220, the plurality of bridge circuits 211 and 221 may be arranged to overlap in the vertical direction Z. Accordingly, the number of multiple bridge circuits 211 and 221 may be increased while minimizing the area of the bridge chip structure 500.

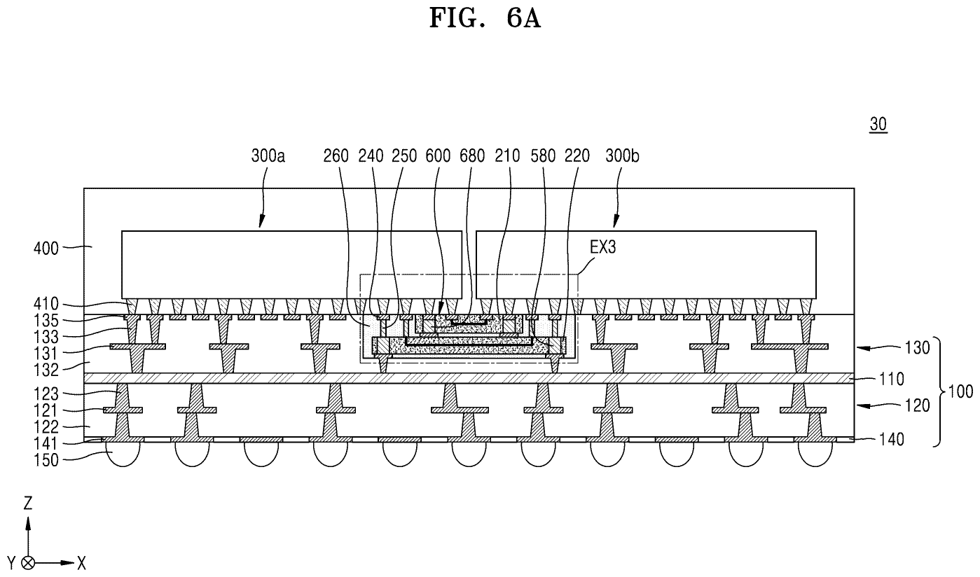

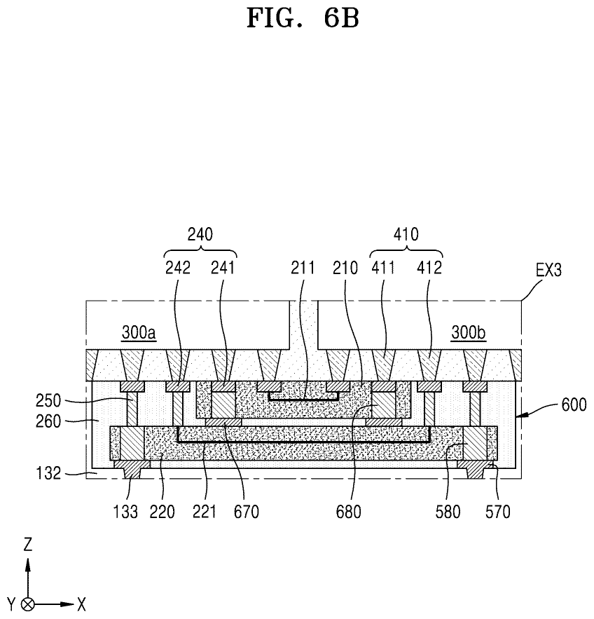

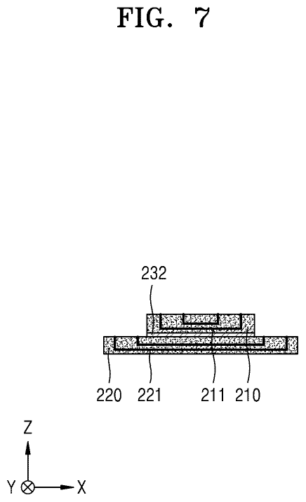

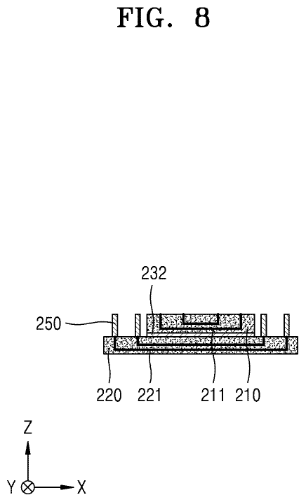

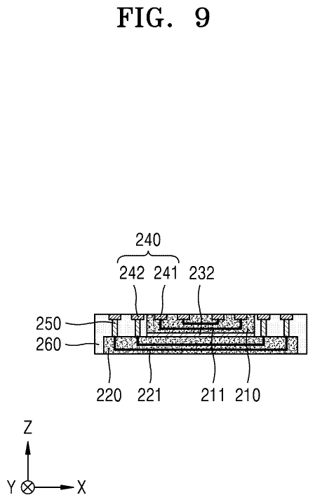

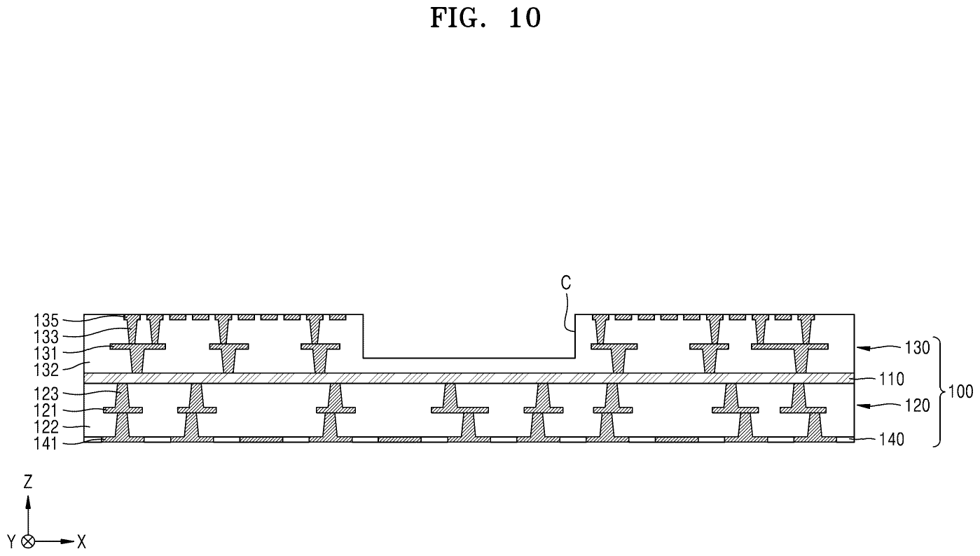

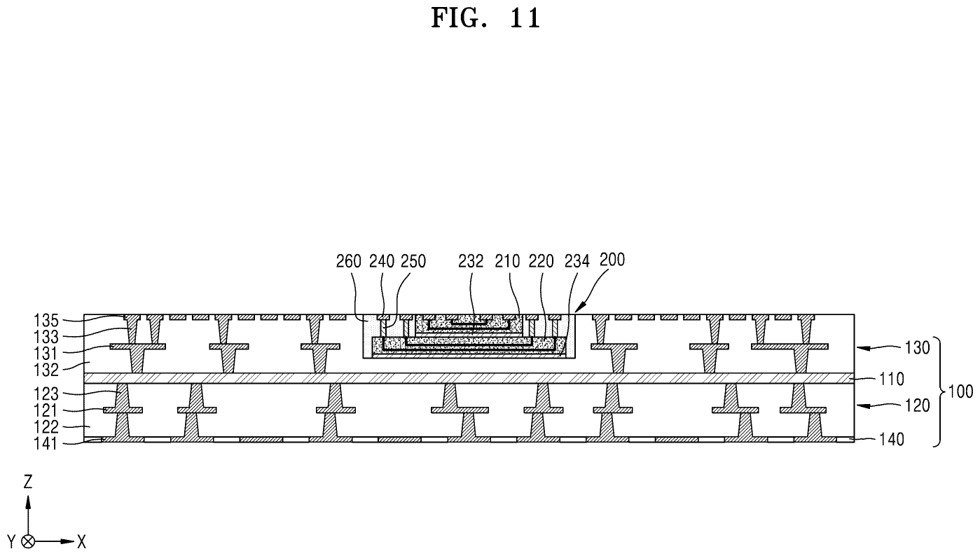

FIG. 6A is a schematic cross-sectional view showing a configuration of a semiconductor package 30 according to an embodiment.

FIG. 6B is an enlarged cross-sectional view of the portion “EX3” of FIG. 6A.

In the description with reference to FIG. 6A and FIG. 6B, like reference numerals as in FIGS. 1 to 3 represent like members, and a detailed description thereof will not be repeated.

Referring to FIG. 6A and FIG. 6B, a bridge chip structure 600 of the semiconductor package 30 according to an embodiment may include a plurality of bridge chips stacked in the vertical direction Z. For example, the bridge chip structure 600 may include a first bridge chip 210 and a second bridge chip 220.

In example embodiments, the second bridge chip 220 may further include a first through-via 580, and the first bridge chip 210 may further include a second through-via 680. The first through-via 580 may penetrate the second bridge chip 220 in the vertical direction Z, and the second through-via 680 may penetrate the first bridge chip 210 in the vertical direction Z. At this time, the first through-via 580 and the second through-via 680 may be TSVs but are not limited thereto. In FIGS. 6A and 6B, the first through-via 580 and the second through-via 680 are illustrated as being arranged at positions where they do not overlap each other in the vertical direction Z but are not limited thereto. For example, the first through-via 580 and the second through-via 680 may be arranged at positions where they overlap each other in the vertical direction Z.

In example embodiments, the first through-via 580 may be electrically connected to a plurality of vertical wires 250. That is, the first through-via 580 may be electrically connected to the second region of the plurality of semiconductor chips 300a and 300b through the plurality of vertical wires 250. The second through-via 680 may be electrically connected to the first region of the plurality of semiconductor chips 300a and 300b through the first upper bridge pad 241.

In example embodiments, the bridge chip structure 600 may further include a plurality of lower bridge pads 570 and a plurality of intermediate bridge pads 670. The lower bridge pad 570 may be in contact with the first through-via 580, and the intermediate bridge pad 670 may be in contact with the second through-via 680. The first through-via 580 may be electrically connected to the package substrate 100 through the lower bridge pad 570 and the upper conductive via 133 of the upper wiring structure 130. The second through-via 680 may be electrically connected to the second bridge chip 220 through the intermediate bridge pad 670. That is, the bridge chip structure 600 may be electrically connected to a plurality of semiconductor chips 300a and 300b and a package substrate 100 through the lower bridge pad 570 and the intermediate bridge pad 670.

At this time, the second adhesive layer 234 (see FIG. 1) configured to bond the second bridge chip 220 and the upper wiring structure 130 of the package substrate 100 may be omitted. The plurality of lower bridge pads 570 may be arranged between the second bridge chip 220 and the upper wiring structure 130 of the package substrate 100. The first adhesive layer 234 (see FIG. 1) configured to bond the first bridge chip 210 and the second bridge chip 220 may be omitted. The plurality of intermediate bridge pads 670 may be arranged between the first bridge chip 210 and the second bridge chip 220. In addition, the encapsulation layer 260 may cover between the first bridge chip 210 and the second bridge chip 220, between the second bridge chip 220 and the upper wiring structure 130 of the package substrate 100, between the plurality of lower bridge pads 570, and between the plurality of intermediate bridge pads 670.

The semiconductor package 30 according to an embodiment includes the bridge chip structure 600 in which a plurality of bridge chips 210 and 220 are stacked in the vertical direction Z, and thus, the area of the bridge chip structure 600 may be reduced and the integration degree may be improved. By stacking and arranging the plurality of bridge chips 210 and 220 in the vertical direction Z,, the plurality of bridge circuits 211 and 221 may be arranged to overlap in the vertical direction Z. Therefore, the number of a plurality of bridge circuits 211 and 221 may be increased while minimizing the area of the bridge chip structure 600.

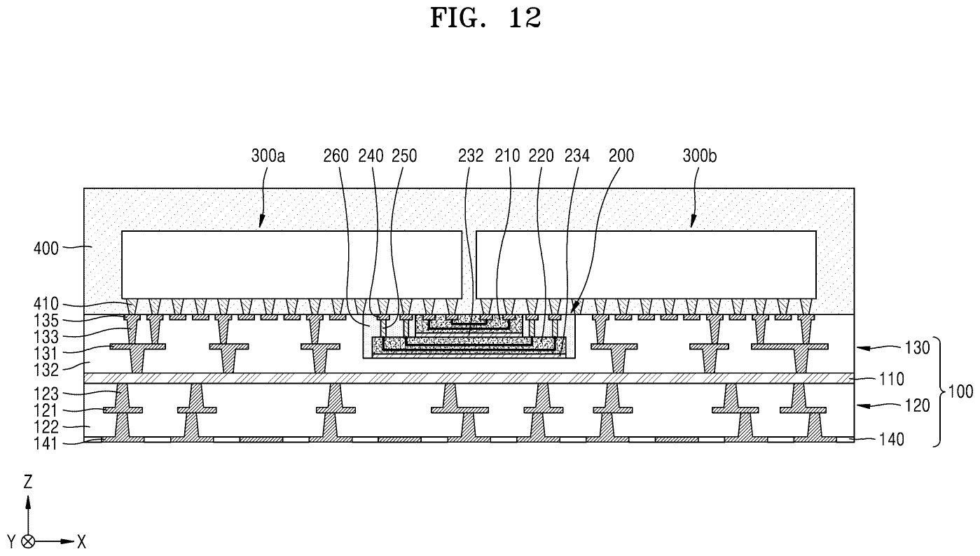

FIGS. 7 to 12 are cross-sectional views sequentially showing a method of manufacturing a semiconductor package according to an embodiment.

In the description with reference to FIGS. 7 to 12, the like numerals as in FIGS. 1 to 3 represent like members, and a detailed description thereof will not be repeated.

Referring to FIG. 7, a first bridge chip 210 may be attached to a second bridge chip 220. A lower surface of the first bridge chip 210 and an upper surface of the second bridge chip 220 may be bonded using a first adhesive layer 232. At this time, the first bridge chip 210 may include a first bridge circuit 211, and the second bridge chip 220 may include a second bridge circuit 221. The first bridge chip 210 and the second bridge chip 220 may have different sizes. For example, the first bridge chip 210 may have a first width in the first horizontal direction X, and the second bridge chip 220 may have a second width greater than the first width in the first horizontal direction X.

Referring to FIG. 8, a plurality of vertical wires 250 may be formed. The plurality of vertical wires 250 may be connected to the second bridge circuit 221 of the second bridge chip 220 and may be formed to extend in the vertical direction Z. The plurality of vertical wires 250 may be arranged to be spaced apart from the first bridge chip 210 in the first horizontal direction X. In addition, the plurality of vertical wires 250 may be arranged to be spaced apart from each other in the first horizontal direction X with the first bridge chip 210 therebetween. At this time, a length of the plurality of vertical wires 250 in the vertical direction Z may be greater than a height of the first bridge chip 210 in the vertical direction Z.

Referring to FIG. 9, an encapsulation layer 260 covering the first bridge chip 210, the second bridge chip 220, and the plurality of vertical wires 250 may be formed. Thereafter, an upper surface of the encapsulation layer 260 may be flattened. For example, the upper surface of the encapsulation layer 260 is flattened through a grinding process, and thus, the upper surface of the encapsulation layer 260 and an upper surface of the first bridge chip 210 may form a coplanar.

Afterwards, a plurality of upper bridge pads 240 including a plurality of first upper bridge pads 241 and a plurality of second upper bridge pads 242 may be formed. The plurality of first upper bridge pads 241 may be electrically connected to the first bridge circuit 211 of the first bridge chip 210, and the plurality of second upper bridge pads 242 may be electrically connected to the second bridge circuit 221 of the second bridge chip 220.

Referring to FIG. 10, a package substrate 100 may be prepared. The package substrate 100 may include, for example, a ceramic substrate, a PCB, an organic substrate, an interposer substrate, etc. The package substrate 100 may include a core layer 110, a lower wiring structure 120, an upper wiring structure 130, and a protective layer 140. At this time, a cavity C may be formed in the upper wiring structure 130.

Referring to FIG. 11, a bridge chip structure 200 may be placed in the cavity C (see FIG. 10) of the package substrate 100. The bridge chip structure 200 may be attached to the upper wiring structure 130 through a second adhesive layer 234. A lower surface of the second bridge chip 220 and an upper surface of the upper wiring structure 130 may be bonded using the second adhesive layer 234. Thereafter, the encapsulation layer 260 that fills a space between the bridge chip structure 200 and the cavity C may be additionally formed.

Referring to FIG. 12, a plurality of semiconductor chips 300a and 300b may be placed on the package substrate 100. At this time, the plurality of semiconductor chips 300a and 300b may be electrically connected to the bridge chip structure 200 and/or the upper wiring structure 130 through a plurality of connection terminals 410. Specifically, the plurality of connection terminals 410 may be electrically connected to the bridge chip structure 200 through the plurality of upper bridge pads 240, and the plurality of connection terminals 410 may be electrically connected to the upper wiring structure 130 through the plurality of upper pads 135. Afterwards, a sealant 400 covering the plurality of semiconductor chips 300a and 300b, the upper surface of the upper wiring structure 130 and the connection terminals 410 may be formed.

Referring again to FIG. 1, the plurality of external connection terminals 150 may be formed on each of a plurality of lower pads 141 to manufacture the semiconductor package 10 according to an embodiment.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
a bridge chip structure including a plurality of bridge chips that are accommodated in the package substrate and are stacked in a vertical direction; and
a plurality of semiconductor chips that are arranged on the package substrate and are electrically connected to each other through the bridge chip structure,
wherein the plurality of bridge chips have different sizes.

2. The semiconductor package of claim 1, wherein the plurality of bridge chips include:
a first bridge chip having a first width in a first horizontal direction; and
a second bridge chip attached to a lower surface of the first bridge chip and having a second width in the first horizontal direction,
wherein the second width is greater than the first width.

3. The semiconductor package of claim 2, wherein each of the plurality of semiconductor chips includes:
a first region electrically connected to the first bridge chip; and
a second region electrically connected to the second bridge chip.

4. The semiconductor package of claim 3, wherein the bridge chip structure further includes a plurality of vertical wires electrically connecting the second regions of the plurality of semiconductor chips and the second bridge chip to each other.

5. The semiconductor package of claim 4, wherein the plurality of vertical wires are spaced apart from each other in the first horizontal direction with the first bridge chip between the plurality of vertical wires.

6. The semiconductor package of claim 4, wherein a vertical length of the plurality of vertical wires is greater than or equal to a vertical height of the first bridge chip.

7. The semiconductor package of claim 2, wherein the bridge chip structure further includes:
a first adhesive layer provided between the first bridge chip and the second bridge chip in the vertical direction; and
a second adhesive layer provided between the second bridge chip and the package substrate.

8. The semiconductor package of claim 2,
wherein the first bridge chip includes a first bridge circuit extending in the first horizontal direction and electrically connecting the first regions of the plurality of semiconductor chips to each other, and
wherein the second bridge chip includes a second bridge circuit that extends in the first horizontal direction and electrically connects the second regions of the plurality of semiconductor chips to each other.

9. The semiconductor package of claim 1, wherein the plurality of bridge chips has a size increasing away from an upper surface of the package substrate.

10. A semiconductor package comprising:
a package substrate;
a bridge chip structure including a plurality of bridge chips accommodated in the package substrate and stacked in a vertical direction of the semiconductor package; and
a plurality of semiconductor chips arranged on the package substrate and electrically connected to each other through the bridge chip structure,
wherein the plurality of bridge chips include:
a first bridge chip having a first width in a first horizontal direction; and
a second bridge chip attached to a lower surface of the first bridge chip and having a second width greater than the first width in the first horizontal direction, and
wherein the second bridge chip further includes a first through-via passing through the second bridge chip in the vertical direction.

11. The semiconductor package of claim 10, wherein each of the plurality of semiconductor chips includes:
a first region electrically connected to the first bridge chip; and
a second region electrically connected to the second bridge chip.

12. The semiconductor package of claim 11, wherein the bridge chip structure further includes a plurality of vertical wires electrically connecting the second regions of the plurality of semiconductor chips and the second bridge chip to each other.

13. The semiconductor package of claim 12, wherein the first through-via is electrically connected to at least one of the first bridge chip, the package substrate, and the vertical wires.

14. The semiconductor package of claim 10, wherein the first through-via is arranged at a position of the second bridge chip that does not overlap the first bridge chip in the vertical direction.

15. The semiconductor package of claim 10, wherein the first bridge chip further includes a second through-via passing through the first bridge chip and electrically connected to the second bridge chip.

16. The semiconductor package of claim 15, wherein the bridge chip structure further includes:
a lower bridge pad electrically connecting the first through-via and the package substrate to each other; and
a intermediate bridge pad connecting the second through-via and the second bridge chip to each other.

17. The semiconductor package of claim 15, wherein the first through-via and the second through-via are arranged at positions overlapping in the vertical direction.

18. A semiconductor package comprising:
a package substrate including a wiring structure and a cavity;
a bridge chip structure disposed in the cavity of the package substrate and including a first bridge chip and a second bridge chip, wherein the first bridge chip is accommodated in the package substrate and has a first width in a first horizontal direction, and the second bridge chip is disposed vertically, stacked on a lower surface of the first bridge chip and has a second width greater than the first width in the first horizontal direction; and
a plurality of semiconductor chips, each of which include a first region and a second region, wherein the first region is electrically connected to the first bridge chip, the second region is electrically connected to the second bridge chip, and the first region and the second region are arranged on the package substrate in the first horizontal direction,
wherein the bridge chip structure further includes a plurality of vertical wires electrically connecting the second region of the plurality of semiconductor chips and the second bridge chip to each other.

19. The semiconductor package of claim 18,
wherein the first bridge chip includes a first bridge circuit that extends in the first horizontal direction and electrically connects the first regions of the plurality of semiconductor chips to each other, and
wherein the second bridge chip includes a second bridge circuit that extends in the first horizontal direction and electrically connects the second regions of the plurality of semiconductor chips to each other.

20. The semiconductor package of claim 18, wherein the second bridge chip further includes at least one through via passing through the second bridge chip and electrically connected to at least one vertical wire among the plurality of vertical wires.
